(19) United States
(12) Patent Application Publication
(10) Pub. No.: US 2024/0239703 A1
(43) Pub. Date: Jul. 18, 2024

(54) GLASS COMPOSITION, GLASS ARTICLE MADE FROM THE GLASS COMPOSITION, AND DISPLAY DEVICE

(71) Applicants: Samsung Display Co., LTD., Yongin-si (KR); Kongju National University Industry-University Cooperation Foundation, Gongju-si (KR)

(72) Inventors: Hui Yeon SHON, Yongin-si (KR); Woon Jin CHUNG, Seongnam-si (KR); Min Gyeong KANG, Jinju-si (KR); Seung KIM, Yongin-si (KR); Seung Ho KIM, Yongin-si (KR); Kyeong Dae PARK, Cheonan-si (KR); Seong Young PARK, Cheonan-si (KR); Cheol Min PARK, Yongin-si (KR); Gyu In SHIM, Yongin-si (KR); Jae Gil LEE, Yongin-si (KR); Jin Won JANG, Yongin-si (KR); So Mi JUNG, Yongin-si (KR)

(21) Appl. No.: 18/371,086

(22) Filed: Sep. 21, 2023

(30) Foreign Application Priority Data
Jan. 16, 2023 (KR) 10-2023-0006284

(51) Int. Cl. C03C 3/093; C03C 3/085; H05K 5/03

(52) U.S. Cl. CPC C03C 3/093; C03C 3/085; H05K 5/03

(57) ABSTRACT

A glass composition, a glass article prepared therefrom, and a display device are provided. The glass article includes as a glass composition: 59 to 69 mol % of SiO₂, 8 to 18 mol % of Al₂O₃, greater than 0 to 5 mol % of Na₂O, greater than 0 to 5 mol % of ZnO, and greater than 0 to 10 mol % of B₂O₃, and glass article further includes 10 to 20 mol % of CaO or 15 to 25 mol % of MgO, satisfies Relation 1 below, and has a thickness of 100 μm or less,

4.5≤Al₂O₃/Na₂O≤5.5 (Relation 1),

where, in Relation 1, Al₂O₃ and Na₂O represent contents (mol %) of corresponding components, respectively, in the glass composition.

This application claims to Korean Patent Application No. 10-2023-0006284, filed on Jan. 16, 2023, and all the benefits accruing therefrom under 35 U.S.C. § 119, the content of which in its entirety is herein incorporated by reference.

### BACKGROUND

### 1. Field

The present disclosure relates to a glass composition, a glass article made from the glass composition, and a display device.

### 2. Description of the Related Art

A glass article is widely used in an electronic device including a display device, building materials, and the like. For example, the glass article is applied to a substrate of a flat panel display device, such as a liquid crystal display (“LCD”), an organic light emitting display (“OLED”) or an electrophoretic display, or to a cover window for protecting the display device.

As a portable electronic device such as a smart phone and a tablet PC increases, the glass article applied to the portable electronic device is frequently exposed to external impacts. Therefore, it is desirable to develop a glass article that is thin for portability and can withstand external impacts.

A display device that can be folded for user convenience has been researched. A desired glass article applied to the foldable display device may have a thin thickness to relieve bending stress when folded and at the same time may have sufficient strength to withstand external impacts. Accordingly, attempts have been made to improve the strength of a thin glass article by changing the component ratio of a composition of the glass article and the conditions of a manufacturing process.

### SUMMARY

Aspects of the present disclosure provide a glass composition having a novel composition ratio, a glass article made from the glass composition, and a display device including the glass article.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, a glass article includes as a glass composition: 59 to 69 mol % of SiO₂, 8 to 18 mol % of Al₂O₃, greater than 0 to 5 mol % of Na₂O, greater than 0 to 5 mol % of ZnO, and greater than 0 to 10 mol % of B₂O₃, and the glass article further includes 10 to 20 mol % of CaO or 15 to 25 mol % of MgO, satisfies Relation 1 below, and has a thickness of 100 μm or less:

4.5≤Al₂O₃/Na₂O≤5.5 (Relation 1),

wherein, in Relation 1, Al₂O₃ and Na₂O represent contents (mol %) of corresponding components, respectively, in the glass composition.

In an embodiment, the thickness of the glass article may be in a range of 20 to 100 μm.

In an embodiment, a thermal expansion coefficient of the glass article may be in a range of 25*10⁻⁷ K⁻¹ to 40*10⁻⁷ K⁻¹.)

In an embodiment, a glass transition temperature of the glass article may be in a range of 700 to 800° C.

In an embodiment, a density of the glass article may be in a range of 2.45 to 2.60 grams per cubic centimeters (g/cm³).

In an embodiment, an elastic modulus of the glass article may be in a range of 80 to 95 GPa.

In an embodiment, a Poisson ratio of the glass article may be in a range of 0.24 to 0.26.

In an embodiment, a hardness of the glass article may be in a range of 7.0 to 7.5 GPa.

In an embodiment, a fracture toughness of the glass article may be in a range of 0.95 to 1.10 MPa*m^{0.5}.

In an embodiment, a brittleness of the glass article may be in a range of 6.5 to 8.0 μm^{-0.5}. In an embodiment, a crack initiation load of the glass article may be in a range of 150 to 550 gf.

According to an aspect of the present disclosure, a glass composition includes: 59 to 69 mol % of SiO₂, 8 to 18 mol % of Al₂O₃, greater than 0 to 5 mol % of Na₂O, greater than 0 to 5 mol % of ZnO, and greater than 0 to 10 mol % of B₂O₃, and the glass composition further includes 10 to 20 mol % of CaO or 15 to 25 mol % of MgO, and satisfies Relation 1 below:

4.5≤Al₂O₃/Na₂O≤5.5 (Relation 1),

where, in Relation 1, Al₂O₃ and Na₂O represent contents (mol %) of corresponding components, respectively, in the glass composition.

According to an aspect of the present disclosure, a display device includes: a display panel including a plurality of pixels, a cover window disposed on the display panel, and an optically clear bonding layer disposed between the display panel and the cover window, where the cover window includes, as a glass composition: 59 to 69 mol % of SiO₂, 8 to 18 mol % of Al₂O₃, greater than 0 to 5 mol % of Na₂O, greater than 0 to 5 mol % of ZnO, and greater than 0 to 10 mol % of B₂O₃, further includes 10 to 20 mol % of CaO or 15 to 25 mol % of MgO, satisfies Relation 1 below, and has a thickness of 100 μm or less:

4.5≤Al₂O₃/Na₂O≤5.5 (Relation 1),

where, in Relation 1, Al₂O₃ and Na₂O represent contents (mol %) of corresponding components, respectively, in the glass composition.

In an embodiment, the cover window may have a thickness of 20 to 100 μm.

In an embodiment, the cover window may have a thermal expansion coefficient of 25*10⁻⁷ K⁻¹ to 40*10⁻⁷ K⁻¹.

In an embodiment, the cover window may have a glass transition temperature of 700 to 800° C.

In an embodiment, the cover window may have a density of 2.45 to 2.60 g/cm³.

In an embodiment, the cover window may have an elastic modulus of 80 to 95 GPa.

In an embodiment, the cover window may have a Poisson ratio of 0.24 to 0.26.

In an embodiment, the cover window may have a hardness of 7.0 to 7.5 GPa.

In an embodiment, the cover window may have a fracture toughness of 0.95 to 1.10 MPa*m^{0.5}.

In an embodiment, the cover window may have a brittleness of 6.5 to 8.0 μm^{-0.5}.

In an embodiment, the cover window may have a crack initiation load of 150 to 550 gf.

A glass composition according to an embodiment may have a novel composition ratio of components, and a glass article made from the glass composition may have excellent mechanical strength, surface strength, and impact resistance properties while having flexibility. In addition, the glass article may have excellent flexibility and strength to the extent that it can be applied to a foldable display device.

However, the effects of the present disclosure are not restricted to the one set forth herein. The above and other effects of the present disclosure will become more apparent to one of daily skill in the art to which the present disclosure pertains by referencing the claims.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of glass articles according to various embodiments;

FIG. 2 is a perspective view illustrating an unfolded state of a display device to which a glass article according to an embodiment is applied;

FIG. 3 is a perspective view illustrating a folded state of the display device of FIG. 2;

FIG. 4 is a cross-sectional view illustrating an example in which a glass article according to an embodiment is applied as a cover window of a display device;

FIG. 5 is a cross-sectional view of a flat plate-shaped glass article according to an embodiment;

FIG. 6 is a graph illustrating a stress profile of the glass article according to the embodiment;

FIG. 7 is a flowchart illustrating operations in a process of manufacturing a glass article according to an embodiment; and

FIG. 8 is a schematic diagram illustrating a series of operations from a cutting operation to a post-tempering surface polishing operation of FIG. 7.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Hereinafter, embodiments will be described with reference to the accompanying drawings.

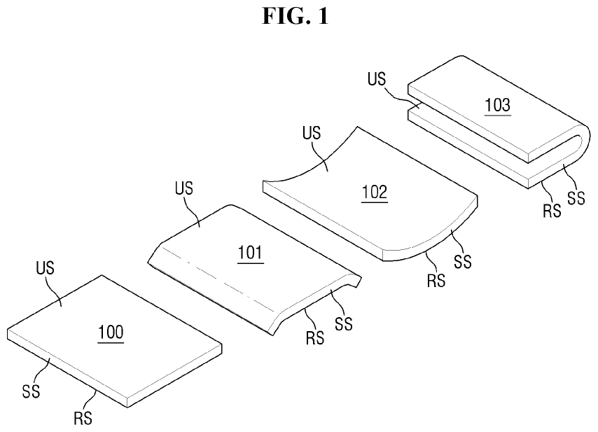

FIG. 1 is a perspective view of glass articles according to various embodiments.

Glass is used as a cover window for protecting a display, a substrate for a display panel, a substrate for a touch panel, an optical member such as a light guide plate, etc. in electronic devices including displays such as tablet PCs, notebook PCs, smartphones, electronic books, televisions and PC monitors as well as refrigerators and washing machines including display screens. The glass may also be used for cover glass of vehicle dashboards, cover glass of solar cells, building interior materials, and windows of buildings or houses.

Glass is desirable to have great strength. For example, glass for windows is desirable to be thin to have high transmittance and light weight but desirable to be strong enough not to be easily broken by an external impact. Glass with increased strength may be produced using a method such as chemical tempering or thermal tempering. Examples of tempered glass having various shapes are illustrated in FIG. 1.

Referring to FIG. 1, in an embodiment, a glass article 100 may be in the shape of a flat sheet or a flat plate. In other embodiments, glass articles 101 through 103 may have a three-dimensional (“3D”) shape including a bent portion. For example, a glass article may have edges of a flat portion bent (see ‘101’), may be generally curved (see ‘102’), or may be folded (see ‘103’). Alternatively, the glass article 100 may be shaped like a flat sheet or a flat plate but may have flexibility so that it can be folded, stretched, or rolled.

The glass articles 100 through 103 may have a rectangular planar shape. However, the glass articles 100 through 103 are not limited to the rectangular planar shape and may also have various planar shapes such as a rectangle with rounded corners, a square, a circle, and an oval. In the following embodiments, a flat plate having a rectangular planar shape will be described as an example of the glass articles 100 through 103.

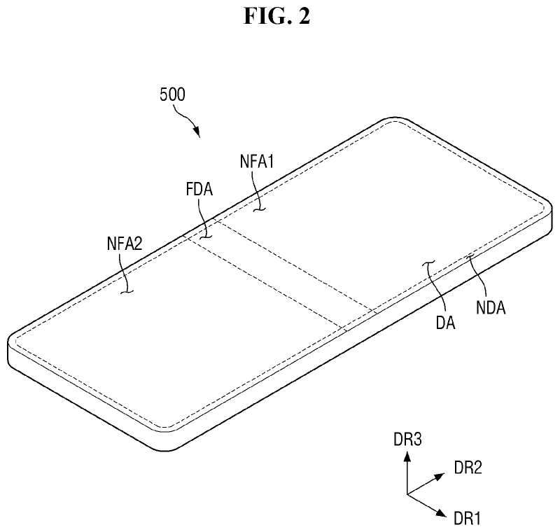

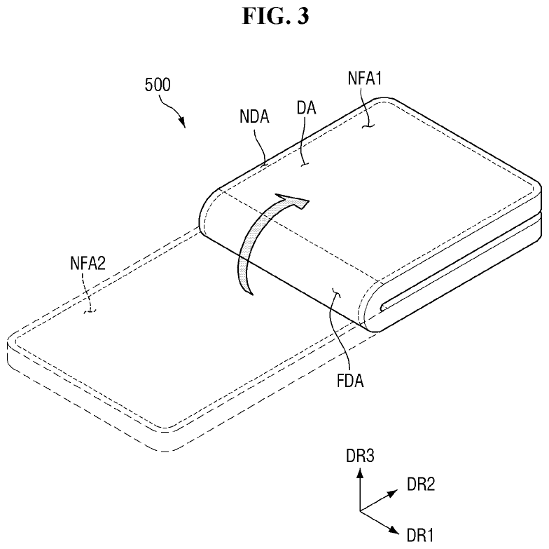

FIG. 2 is a perspective view illustrating an unfolded state of a display device to which a glass article according to an embodiment is applied. FIG. 3 is a perspective view illustrating a folded state of the display device 500 of FIG. 2.

Referring to FIGS. 2 and 3, a display device 500 according to the embodiment may be a foldable display device. As will be described later, the glass article 100 of FIG. 1 may be applied to the display device 500 as a cover window. The glass article 100 may have flexibility so that it can be folded.

In FIGS. 2 and 3, a first direction DR1 may be a direction parallel to a side of the display device 500 in plan view, for example, a horizontal direction of the display device 500. A second direction DR2 may be a direction parallel to another side of the display device 500 in contact with the above side in plan view, for example, a vertical direction of the display device 500. A third direction DR3 may be a thickness direction of the display device 500.

In an embodiment, the display device 500 may be rectangular in plan view. The display device 500 may be shaped like a rectangle with perpendicular corners or a rectangle with rounded corners in plan view. The display device 500 may include two short sides disposed in the first direction DR1 and two long sides disposed in the second direction DR2 in plan view.

The display device 500 includes a display area DA and a non-display area NDA. The shape of the display area DA may correspond to the shape of the display device 500 in plan view. For example, when the display device 500 is rectangular in plan view, the display area DA may also be rectangular.

The display area DA may include a plurality of pixels to display an image. The pixels may be arranged in a matrix direction. Each of the pixels may be shaped like a rectangle, a rhombus, or a square in plan view. However, the present disclosure is not limited thereto. For another example, each of the pixels may also be shaped like a quadrilateral other than a rectangle, a rhombus or a square, a circle, or an oval in plan view.

The non-display area NDA may not display an image because it does not include pixels. The non-display area NDA may be disposed around the display area DA. The non-display area NDA may surround the display area DA. However, the present disclosure is not limited thereto. The display area DA may also be partially surrounded by the non-display area NDA in another embodiment.

In an embodiment, the display device 500 may maintain both the folded state and the unfolded state. The display device 500 may be folded in an in-folding manner in which the display area DA is disposed inside as illustrated in FIG. 3. When the display device 500 is folded in the in-folding manner, portions of an upper surface of the display device 500 may face each other. Alternatively, the display device 500 may be folded in an out-folding manner in which the display area DA is disposed outside. When the display device 500 is folded in the out-folding manner, portions of a lower surface of the display device 500 may face each other.

In an embodiment, the display device 500 may be a foldable device. In the present specification, the term “foldable device” is used to refer to devices that can be folded, including not only a folded device but also a device that can have both the folded state and the unfolded state. In addition, folding typically includes folding at an angle of about 180 degrees. However, the present disclosure is not limited thereto, and folding at an angle of more than or less than 180 degrees, such as folding at an angle of 90 to less than 180 degrees or an angle of 120 to less than 180 degrees may also be understood as folding. Furthermore, even an incompletely folded state may also be referred to as the folded state if it is not the unfolded state. For example, even a folded state at an angle of 90 degrees or less may be expressed as the folded state to distinguish it from the unfolded state as long as a maximum folding angle is 90 degrees or more. The radius of curvature at the time of folding may be 5 millimeters (mm) or less, preferably, 1 to 2 mm or about 1.5 mm. However, the present disclosure is not limited thereto.

In an embodiment, the display device 500 may include a folding area FDA, a first non-folding area NFA1, and a second non-folding area NFA2. The folding area FDA may be an area in which the display device 500 is folded, and the first non-folding area NFA1 and the second non-folding area NFA2 may be areas in which the display device 500 is not folded.

The first non-folding area NFA1 may be disposed on a side, e.g., an upper side of the folding area FDA. The second non-folding area NFA2 may be disposed on the other side, e.g., a lower side of the folding area FDA. The folding area FDA may be an area bent with a predetermined curvature.

In an embodiment, the folding area FDA of the display device 500 may be set at a specific position. In the display device 500, one folding area FDA or two or more folding areas FDA may be set at a specific position. In an embodiment, the folding area FDA may not be limited to a specific position in the display device 500 but may be freely set in various areas.

In an embodiment, the display device 500 may be folded in the second direction DR2. As a result, a length of the display device 500 in the second direction DR2 may be reduced to about half Therefore, a user can easily carry the display device 500.

In an embodiment, the direction in which the display device 500 is folded is not limited to the second direction DR2. For example, the display device 500 may also be folded in the first direction DR1. In this case, the length of the display device 500 in the first direction DR1 may be reduced to about half.

In the drawings, each of the display area DA and the non-display areaNDA overlaps the folding area FDA, the first non-folding area NFA1, and the second non-folding area NFA2. However, the present disclosure is not limited thereto. For another example, each of the display area DA and the non-display area NDA may overlap at least one of the folding area FDA, the first non-folding area NFA1, and the second non-folding area NFA2.

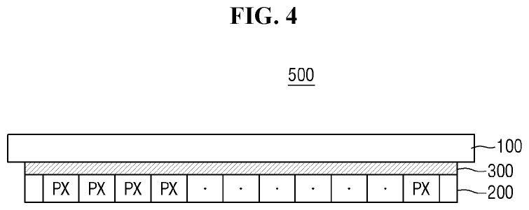

FIG. 4 is a cross-sectional view illustrating an example in which a glass article according to an embodiment is applied as a cover window of a display device.

Referring to FIG. 4, the display device 500 may include a display panel 200, the glass article 100 disposed on the display panel 200 and serving as a cover window, and an optically clear bonding layer 300 disposed between the display panel 200 and the glass article 100 to bond the display panel 200 and the glass article 100 together.

In an embodiment, the display panel 200 may be, for example, a self-luminous display panel such as an organic light emitting display panel (OLED), an inorganic electroluminescent (“EL”) display panel, a quantum dot light emitting display panel (“QED”), a micro-light emitting diode (“LED”) display panel, a nano-LED display panel, a plasma display panel (“PDP”), a field emission display panel (“FED”) or a cathode ray tube (“CRT”) display panel or may be a light receiving display panel such as a liquid crystal display (LCD) panel or an electrophoretic display (“EPD”) panel.

The display panel 200 may include a plurality of pixels PX and may display an image using light emitted from each pixel PX. The display device 500 may further include a touch member (not illustrated). In an embodiment, the touch member may be internalized in the display panel 200. For example, the touch member may be directly disposed on a display member of the display panel 200 so that the display panel 200 itself can perform a touch function. In an embodiment, the touch member may be manufactured separately from the display panel 200 and then attached to an upper surface of the display panel 200 by an optically clear bonding layer.

The glass article 100 is disposed on the display panel 200 to protect the display panel 200. The glass article 100 may be larger in size than the display panel 200. Thus, side surfaces of the glass article 100 may protrude outward from side surfaces of the display panel 200, but the present disclosure is not limited to this case. The display device 500 may further include a printed layer (not illustrated) disposed on at least one surface of the glass article 100 in an edge portion of the glass article 100. The printed layer may prevent a bezel area of the display device 500 from being visible from the outside and, in some cases, may perform a decorative function.

The optically clear bonding layer 300 is disposed between the display panel 200 and the glass article 100. The optically clear bonding layer 300 fixes the glass article 100 on the display panel 200. The optically clear bonding layer 300 may include an optical clear adhesive (“OCA”) or an optical clear resin (“OCR”).

The tempered glass article 100 described above will now be described in more detail.

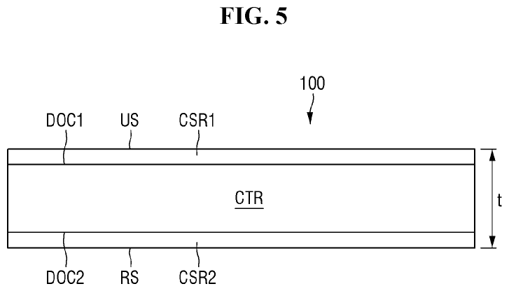

FIG. 5 is a cross-sectional view of a flat plate-shaped glass article 100 according to an embodiment.

Referring to FIG. 5, the glass article 100 may include a first surface US, a second surface RS, and side surfaces. The first surface US and the second surface RS of the flat plate-shaped glass article 100 are main surfaces having a large area, and the side surfaces are outer surfaces connecting the first surface US and the second surface RS.

The first surface US and the second surface RS face each other in the thickness direction. When the glass article 100 serves to transmit light like a cover window of a display, the light may usually be incident on any one of the first surface US and the second surface RS and then transmitted to the other surface.

A thickness t of the glass article 100 is defined as a distance between the first surface US and the second surface RS. The thickness t of the glass article 100 may be in the range of, but not limited to, 100 micrometers (μm). or less, preferably be in the range of 20 to 100 μm. In an embodiment, the thickness t of the glass article 100 may be 80 μm or less. In another embodiment, the thickness t of the glass article 100 may be about 75 μm or less. In an embodiment, the thickness t of the glass article 100 may be about 70 μm or less. In another embodiment, the thickness t of the glass article 100 may be about 60 μm or less. In another embodiment, the thickness t of the glass article 100 may be about 65 μm or less. In another embodiment, the thickness t of the glass article 100 may be about 50 μm or less. In another embodiment, the thickness t of the glass article 100 may be about 30 μm or less. In some specific embodiments, the thickness t of the glass article 100 may be in the range of 20 to 50 μm or may have a value of about 30 μm. The glass article 100 may have a uniform thickness t. However, the present disclosure is not limited thereto, and the glass article 100 may also have a different thickness t in each region.

The glass article 100 may be tempered to have a predetermined stress profile therein. The glass article 100 after being tempered better prevents crack generation, crack propagation, and breakage due to an external impact than the glass article 100 before being tempered. The glass article 100 tempered through a tempering process may have various stresses in different regions. For example, compressive regions CSR1 and CSR2 in which compressive stress acts may be disposed near the surfaces of the glass article 100, that is, near the first surface US and the second surface RS, and a tensile region CTR in which tensile stress acts may be disposed inside the glass article 100. A stress value may be zero at boundaries DOC1 and DOC2 between the compressive regions CSR1 and CSR2 and the tensile region CTR. The compressive stress in one compressive region CSR1 or CSR2 may have a different stress value according to position (i.e., depth from the surface). In addition, the tensile region CTR may have a different stress value according to depth from the surface US or RS.

Positions of the compressive regions CSR1 and CSR2 in the glass article 100, stress profiles in the compressive regions CSR1 and CSR2, and compressive energies of the compressive regions CSR1 and CSR2 or tensile energy of the tensile region CTR may greatly affect mechanical properties (such as surface strength) of the glass article 100.

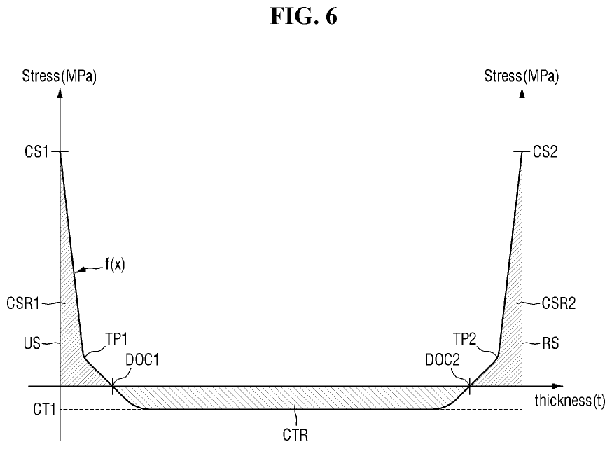

FIG. 6 is a graph illustrating a stress profile of the glass article according to the embodiment of FIG. 5. In the graph of FIG. 6, the x-axis represents the thickness direction of the glass article. In FIG. 6, compressive stress is represented by a positive value, and tensile stress is represented by a negative value. In the present specification, the magnitude of the compressive/tensile stress denotes the magnitude of an absolute value regardless of the sign of the value.

Referring to FIG. 6, the glass article 100 includes a first compressive region CSR1 extending (or expanding) from the first surface US to a first compression depth DOC1 and a second compressive region CSR2 extending (or expanding) from the second surface RS to a second compression depth DOC2. The tensile region CTR is disposed between the first compression depth DOC1 and the second compression depth DOC2. In the overall stress profile of the glass article 100, regions on opposite surface sides US and RS may be symmetrical to each other with respect to a center of the thickness direction. Although not illustrated in FIG. 6, compressive regions and a tensile region may also be disposed between facing side surfaces of the glass article 100 in a similar manner.

The first compressive region CSR1 and the second compressive region CSR2 resist external impacts to prevent generation of cracks in the glass article 100 or breakage of the glass article 100. The greater the maximum compressive stresses CS1 and CS2 of the first and second compressive regions CSR1 and CSR2, the greater the strength of the glass article 100. Since an external impact is usually transmitted through the surfaces of the glass article 100, it is advantageous in terms of durability to have the maximum compressive stresses CS1 and CS2 at the surfaces of the glass article 100. In this regard, the compressive stresses of the first compressive regions CSR1 and the second compressive region CSR2 tend to be greatest at the surfaces and decrease toward the inside of the glass article 100.

The first compression depth DOC1 and the second compression depth DOC2 prevent cracks or grooves formed in the first and second surfaces US and RS from propagating to the tensile region CTR inside the glass article 100. The greater the first and second compression depths DOC1 and DOC2, the better the propagation of cracks can be prevented. Points corresponding to the first compression depth DOC1 and the second compression depth DOC2 correspond to the boundaries between the compressive regions CSR1 and CSR2 and the tensile region CTR and have a stress value of 0.

Throughout the glass article 100, the tensile stress of the tensile region CTR may be balanced with the compressive stresses of the compressive regions CSR1 and CSR2. That is, the total compressive stress (i.e., compressive energy) in the glass article 100 may be equal to the total tensile stress (i.e., tensile energy). The stress energy accumulated in one region having a predetermined width in the thickness direction in the glass article 100 may be calculated by integrating a stress profile. When the stress profile in the glass article 100 having a thickness of t is represented by a function f(x), the following equation may be established.

$${\int }_{0}^{t} f ( x ) dx = 0 \qquad ( 1 )$$

As the magnitude of the tensile stress inside the glass article 100 increases, fragments may be violently expelled when the glass article 100 is broken, and crushing may occur from inside the glass article 100. The maximum tensile stress that meets the fragility criteria of the glass article 100 may satisfy, but not limited to, the following relation.

$${CT}_{1} \leq - 38.7 \times ln ( t ) + 48.2 \qquad ( 2 )$$

In some embodiments, maximum tensile stress CT1 may be 100 Mpa or less or may be 85 MPa or less. A maximum tensile stress CT1 of 75 MPa or more may improve mechanical properties such as strength. In an embodiment, the maximum tensile stress CT1 may be, but is not limited to, 75 to 85 MPa.

The maximum tensile stress CT1 of the glass article 100 may be generally located in a central part of the glass article 100 in the thickness direction. In an embodiment, for example, the maximum tensile stress CT1 of the glass article 100 may be located at a depth of 0.4 to 0.6t, at a depth of 0.45 to 0.55 t, or at a depth of about 0.5 t from the second surface RS, where the thickness of glass article 100 is t.

Large compressive stress and compressive depths DOC1 and DOC2 may be advantageous in increasing the strength of the glass article 100. However, as the compressive energy increases, the tensile energy may also increase, thereby increasing the maximum tensile stress CT1. In order for the glass article 100 to meet the fragility criteria while having high strength, the stress profile may be adjusted to increase the maximum compressive stresses CS1 and CS2 and the compressive depths DOC1 and DOC2 and reduce the compressive energy.

To this end, the glass article 100 may be manufactured using a glass composition including specific components in a predetermined ratio. Depending on the composition ratio of the components included in the glass composition, the manufactured glass article 100 may have excellent strength and, at the same time, may have flexible nature and physical properties that make it applicable to a foldable display device. According to an embodiment, the glass composition that forms the glass article 100 may include 59 to 69 mole percents (mol %) of SiO₂, 8 to 18 mol % of Al₂O₃, greater than 0 to 5 mol % of Na₂O, greater than 0 to 5 mol % of ZnO, and greater than 0 to 10 mol % of B₂O₃, and further include 10 to 20 mol % of CaO or 15 to 25 mol % of MgO of the glass composition. Each component of the glass composition will be described in more detail as follows.

SiO₂ may serve to form the framework of glass, increase chemical durability, and reduce generation of cracks when scratches (indentations) are formed on the glass surface. SiO₂ may be a network former oxide that forms a network of glass, and the glass article 100 manufactured to include SiO₂ may have a reduced coefficient of thermal expansion and improved mechanical strength. To fully perform the above roles, SiO₂ may be included in an amount of 59 mol % or more. To exhibit sufficient meltability, SiO₂ may be included in the glass composition in an amount of 69 mol % or less.

Al₂O₃ serves to improve crushability of glass. That is, Al₂O₃ may cause glass to be fragmented into a smaller number of pieces when the glass is broken. Al₂O₃ may be an intermediate oxide that forms a bond with SiO₂ forming a network structure. In addition, Al₂O₃ may act as an active component that improves ion exchange performance during chemical tempering and increases surface compressive stress after the tempering. When included in an amount of 8 mol % or more, Al₂O₃ may effectively perform the above functions. To maintain acid resistance and meltability of glass, Al₂O₃ may be included in an amount of 18 mol % or less.

Na₂O serves to form surface compressive stress through ion exchange and improve meltability of glass. Na₂O may form non-bridging oxygen in a SiO₂ network structure by forming an ionic bond with oxygen of SiO₂ that forms the network structure. An increase in non-bridging oxygen may improve the flexibility of the network structure and cause the glass article 100 to have physical properties that make it applicable to a foldable display device. Na₂O may effectively perform the above roles when included in an amount of more than 0 mol % or more. However, 5 mol % or less may be desirable in view of acid resistance of the glass article 100.

ZnO may improve water resistance and fluidity of the glass composition. The glass article 100 produced with ZnO can have a reduced coefficient of thermal expansion and improved mechanical strength. In order to sufficiently perform the role described above, ZnO may be included in an amount greater than 0 mol %. ZnO may have a content of 5 mol % or less in the glass composition so that the fluidity of the glass composition is not lowered.

B₂O₃ improves the chemical durability and flexibility of the glass and improves the fusibility. B₂O₃ may also be a network former oxide that forms the network structure together with SiO₂. B₂O₃ has the coordination number of 3 and thus its bonding force is lower than the bonding force of Al₂O₃, which can reduce the modulus of elasticity. Accordingly, when the content of B₂O₃ is more than 0 mol %, it is possible to improve the flexibility of the glass and thus improve the bending characteristics of the foldable display device. In addition, when the B₂O₃ content is 10 mol % or less, striae can be advantageously suppressed during fusing.

MgO may improve the surface strength of glass and reduce the formation temperature of glass. MgO may be a network modifier oxide that modifies a SiO₂ network structure forming a network structure. MgO may increase the viscosity, elastic modulus and hardness of glass. MgO may significantly perform the above functions when contained in an amount of 15 mol % or more. However, 25 mol % or less may be desirable in view of the meltability of the glass article 100.

CaO may improve the surface strength of the glass. CaO may be a network modifier oxide that modifies the SiO₂ network structure forming the network structure. CaO can increase the viscosity, elastic modulus and hardness of glass. CaO can significantly achieve the effect when the CaO content is 10 mol % or greater. On the other hand, in terms of fusibility of the glass article 100, it is desired that the CaO content is 20 mol % or less.

According to an embodiment, the glass composition may satisfy Relation 1 below.

4.5≤Al₂O₃/Na₂O≤5.5 (Relation 1)

where Al₂O₃ and Na₂O represent contents (mol %) of corresponding components, respectively.

As described above, the glass article 100 manufactured using the glass composition according to the embodiment may have characteristics and physical properties that make it applicable to a foldable display device. For example, the glass article 100 may have flexibility so that it can be folded and unfolded and may have strength and chemical properties sufficient to make it applicable as a cover window of the display device 500. A network structure formed by SiO₂, B₂O₃ and Al₂O₃ included in the glass composition may become a flexible network structure by the addition of Na₂O. The addition of Na₂O may cause Na ions to form ionic bonds with oxygen between bonds that form the network structure, for example, bonds between SiO₂, thereby increasing non-bridging oxygen. The increase in non-bridging oxygen in the network structure means that the bonds of the network structure are broken or open. Thus, the network structure of glass may have flexibility. The glass composition may include Na₂O in an amount of more than 0 mol % or more so that the manufactured glass article 100 can have sufficient flexibility.

Since the glass composition includes a relatively excessive amount of Na₂O, mechanical strength may be poor. To compensate for this, the glass composition may include Al₂O₃. Here, the ratio of the Al₂O₃ content to the Na₂O content may be adjusted within the range of 4.5 to 5.5 according to Relation 1 above.

Accordingly, mechanical strength may be added to the network structure. According to an embodiment, the ratio of the Al₂O₃ content to the Na₂O content or the R ratio in the glass composition may be in the range of 4.5 to 5.5. As the ratio of the Al₂O₃ content to the Na₂O content (hereinafter, “R ratio”) in the glass composition increases, the Na₂O content may increase and Al₂O₃ may have a tetrahedron crystal structure formed by SiO₂. In the network structure formed by SiO₂, SiO₂ may have a tetrahedral crystal structure [SiO₄], and if the content of Na₂O and Al₂O₃ are included in similar amounts, Al₂O₃ may also have a tetrahedral crystal structure [AlO₄]. In this case, the content of non-bridging oxygen formed due to the addition of Na₂O may be reduced, and ion mobility of the glass composition may be increased.

The increase in ion mobility means that the amount of ions moving in the chemical strengthening process in the forming process of the glass article 100 increases and the penetration depth of the ions increases, and the mechanical strength of the surface of the glass article 100 may be improved.

When the ratio of the Al₂O₃ content to the Na₂O content (R ratio) in the glass composition is 4.5 or more, the Na₂O content may increase, and the increased Na₂O may break the SiO₂ network structure, thereby increasing the distance between atoms in the network structure. Accordingly, a lot of extra space may be formed in the SiO₂ network structure, and thus shock absorption characteristics can be improved.

In an embodiment, since the ratio of the Al₂O₃ content to the Na₂O content (R ratio) in the glass composition has a value of 4.5 to 5.5, the glass article 100 may have flexibility, sufficient strength against external impacts, and improved shock absorption characteristics.

In an embodiment, the glass composition may include 63.6 mol % of SiO₂, 12.9 mol % of Al₂O₃, 4.7 mol % of B₂O₃, 14.5 mol % of CaO, 1.6 mol % of ZnO and 2.7 mol % of Na₂O, and the R ratio according to Relation 1 above may be 4.77. In another embodiment, the glass composition may include 60.8 mol % of SiO₂, 12.4 mol % of Al₂O₃, 4.6 mol % of B₂O₃, 18.3 mol % of MgO, 1.5 mol % of ZnO and 2.4 mol % of Na₂O, and the R ratio according to Relation 1 above may be 5.16.

In addition, the glass composition may include B₂O₃ to provide flexibility so that the glass article 100 can be folded and unfolded. B₂O₃ may form a glass with a coordination number of 3 to lower the bonding strength, that is, the viscosity. Accordingly, folding and unfolding characteristics of the glass article 100 may be effectively improved by reducing the glass transition temperature and modulus of elasticity of the glass. That is, as the modulus of elasticity of the glass is reduced, the stress applied to the lower portion of the glass article during folding and unfolding is reduced, thereby improving the bending characteristics of the glass article.

In addition, the glass composition may include CaO or MgO. As described above, CaO and MgO may increase the viscosity of the glass composition, the modulus of elasticity and the hardness of the glass. Since the present embodiment discloses increasing the modulus of elasticity and hardness of the glass, any one of CaO and MgO may be included from the viewpoint of improving the strength of the glass.

In addition, the glass composition may have ZnO content that is greater than 0 and less than or equal to 5 mol %. ZnO may lower the coefficient of thermal expansion of glass and increase its mechanical strength. In this embodiment, the impact strength of the glass may be increased by including ZnO.

In an embodiment, the glass composition may include components such as Y₂O₃, La₂O₃, Nb₂O₅, Ta₂O₅ and Gd₂O₃ in addition to the components listed above. In addition, the glass composition may further include trace amounts of Sb₂O₃, CeO₂, and/or As₂O₃ as a refining agent.

The glass composition having the above composition may be molded into the shape of plate glass using various methods known in the art. Once molded into the plate glass shape, the glass composition may be further processed to produce the glass article 100 that can be applied to the display device 500. However, the present disclosure is not limited thereto, and the glass composition may also not be molded into the plate glass shape but may be directly molded into the glass article 100 applicable to a product without an additional molding process in another embodiment.

A process in which the glass composition is molded into the flat glass shape and then processed into the glass article 100 will now be described.

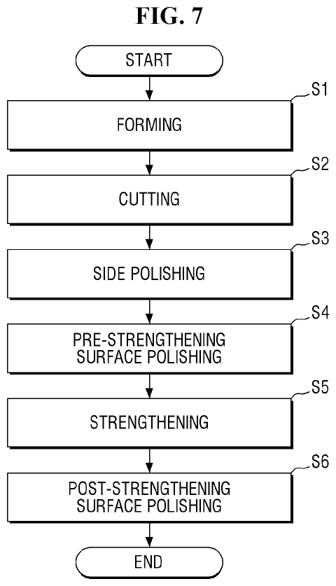

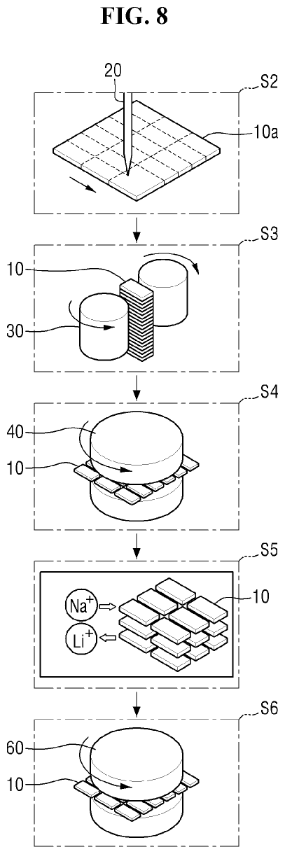

FIG. 7 is a flowchart illustrating operations in a process of manufacturing a glass article according to an embodiment. FIG. 8 is a schematic diagram illustrating a series of operations from a cutting operation to a post-tempering surface polishing operation of FIG. 7.

Referring to FIGS. 7 and 8, a method of manufacturing a glass article 100 may include a molding operation (operation S1), a cutting operation (operation S2), a side polishing operation (operation S3), a pre-tempering surface polishing operation (operation S4), a tempering operation (operation S5), and a post-tempering surface polishing operation (operation S6).

The molding operation (operation S1) may include preparing a glass composition and molding the glass composition. This operation S1 may be referred to as “forming” operation. The glass composition may have the above-described composition and components, which will not be described in detail here. In an embodiment, the glass composition may be molded into a plate glass shape by a method such as a float process, a fusion draw process, or a slot draw process.

The glass molded into the flat plate shape may be cut through the cutting operation (operation S2). The glass molded into the flat plate shape may have a size different from the size applied to a final glass article 100. In an embodiment, for example, glass may be molded in the state of a large-area substrate as a mother substrate 10a including a plurality of glass articles and then may be cut into a plurality of cells to produce a plurality of glass articles. For example, although the final glass article 100 has a size of about 6 inches, glass may be molded to a size (e.g., 120 inches) several to hundreds of times the size of the final glass article 100 and then cut to produce 20 flat plate shapes at once. This can improve process efficiency as compared with when individual glass articles are molded separately. In addition, even when glass corresponding to the size of one glass article is molded, if a final glass article has various planar shapes, a desired shape may be formed through the cutting process.

The cutting of the glass 10a may be performed using a cutting knife 20, a cutting wheel, a laser, or the like.

The glass cutting operation (operation S2) may be performed before the glass tempering operation (operation S5). The glass 10a corresponding to a mother substrate may also be tempered and then cut into final glass article sizes. In this case, however, cut surfaces (e.g., side surfaces) of the glass may not be tempered. Therefore, it is desirable to perform the tempering operation (operation S5) after completing the cutting operation (operation S2).

A pre-tempering polishing operation may be performed between the glass cutting operation (operation S2) and the glass tempering operation (operation S5). The polishing operation may include the side polishing operation (operation S3) and the pre-tempering surface polishing operation (operation S4). In an embodiment, the side polishing operation (operation S3) may be performed before the pre-tempering surface polishing operation (operation S4), but this order can be reversed.

The side polishing operation (operation S3) is an operation of polishing side surfaces of the cut glass 10. In the side polishing operation (operation S3), the side surfaces of the glass cells 10 may be polished to become smooth. In addition, the side surfaces of the glass cells 10 may become even through the side polishing operation (operation S3). More specifically, each glass cell 10 may include one or more cut surfaces. Some of the glass cells 10 may have two cut surfaces out of four side surfaces. Some other glass cells 10 may have three cut surfaces out of four side surfaces. Some other glass cells 10 may have all four side surfaces as cut surfaces. Surface roughness may be different between a cut side surface and an uncut side surface. Surface roughness may also be different even between cut surfaces. Therefore, each side surface may be polished through the side polishing operation (operation S3) to have a uniform surface roughness. Furthermore, if there is a small crack in a side surface, it may also be removed through the side polishing operation (operation S3).

The side polishing operation (operation S3) may be simultaneously performed on the glass cells 10. That is, the glass cells 10 may be stacked and then simultaneously polished.

The side polishing operation (operation S3) may be performed by a mechanical polishing method or a chemical mechanical polishing method using a polishing device 30. In an embodiment, two facing side surfaces of each glass cell 10 may be simultaneously polished, and then the other two facing side surfaces may be simultaneously polished. However, the present disclosure is not limited thereto.

The pre-tempering surface polishing operation (operation S4) may be performed to ensure that each glass cell 10 has an even surface. The pre-tempering surface polishing operation (operation S4) may be performed on the glass cells 10 one by one. However, if a chemical mechanical polishing device 40 is sufficiently larger than the glass cells 10, the glass cells 10 may be arranged horizontally and then may be simultaneously surface-polished.

The pre-tempering surface polishing operation (operation S4) may be performed by a chemical mechanical polishing method. Specifically, a first surface and a second surface of each glass cell 10 are polished using a chemical mechanical polishing device 40 and polishing slurry. The first surface and the second surface may be polished simultaneously, or one surface may be polished first, and then the other surface may be polished.

The tempering operation (operation S5) is performed after the pre-tempering surface polishing operation (operation S4). The tempering operation (operation S5) may be performed as chemical tempering and/or thermal tempering. This operation S5 may be referred to as “strengthening” operation. In the case of a glass cell 10 having a thin thickness of 2 mm or less, by extension, about 0.75 mm or less, a chemical tempering method may be suitably applied for precise stress profile control.

Ater the tempering operation (operation S5), the post-tempering surface polishing operation (operation S6) may be further performed optionally. The post-tempering surface polishing operation (operation S6) may serve to remove fine cracks in the surfaces of the tempered glass cells 10 and control the compressive stress of the first and second surfaces of the tempered glass cells 10. In an embodiment, for example, in a floating method which is one of the plate glass manufacturing methods, a glass composition is poured into a tin bath. In this case, a surface in contact with the tin bath and a surface not in contact with the tin bath may have different compositions. Accordingly, a difference in compressive stress between the surface in contact with the tin bath and the surface not in contact with the tin bath may occur after the tempering of the glass cells 10 (operation S5). This difference in compressive stress between the surface in contact with the tin bath and the surface not in contact with the tin bath may be reduced by removing the surface of each glass cell 10 to an appropriate thickness through polishing.

The post-tempering surface polishing operation (operation S6) may be performed using a chemical mechanical polishing method. Specifically, the first and second surfaces of the tempered glass cells 10, which are the glass cells 10 to be processed, are polished using a chemical mechanical polishing device 60 and polishing slurry. A polishing thickness may be adjusted in the range of, but not limited to, 100 to 1000 nanometers (nm). Polishing thicknesses of the first surface and the second surface may be the same or different.

Although not illustrated in the drawing, a shape machining process may be further performed after the post-tempering surface polishing operation (operation S6). For example, when the 3D glass articles 101 through 103 illustrated in FIG. 1 are to be manufactured, a 3D machining process may be performed after the post-tempering surface polishing operation (operation S6) is completed.

The glass article 100 manufactured through the above processes may have a component ratio similar to the component ratio of the glass composition. In an embodiment, for example, the glass article 100 may include 59 to 69 mol % of SiO₂, 8 to 18 mol % of Al₂O₃, greater than 0 to 5 mol % of Na₂O, greater than 0 to 5 mol % of ZnO, and greater than 0 to 10 mol % of B₂O₃, and further include 10 to 20 mol % of CaO or 15 to 25 mol % of MgO. The glass composition for manufacturing the glass article 100 may satisfy Relation 1 below.

4.5≤Al₂O₃/Na₂O≤5.5 (Relation 1)

where Al₂O₃ and Na₂O represent contents (mol %) of corresponding components, respectively.

According to an embodiment, the glass article 100 made from the glass composition described above may have a thickness of 100 μm or less, preferably, 20 to 100 μm and may satisfy the following physical properties.
i) Coefficient of thermal expansion (10⁻⁷ K⁻¹): 25*10⁻⁷ K⁻¹ to 40*10⁻⁷ K⁻¹
ii) Glass transition temperature (Tg): 700 to 800° C.
iii) Density: 2.45 to 2.60 g/cm³
iv) Modulus of elasticity: 80 to 95 gigapascals (GPa)
v) Poisson ratio: 0.24 to 0.26
vi) Hardness: 7.0 to 7.5 GPa
vii) Fracture toughness: 0.95 to 1.10 MPa*m^{0.5}
viii) Brittleness: 6.5 to 8.0 μm^{-0.5}
ix) Crack initiation load: 150 to 550 gram-force (gf)

Hereinafter, embodiments will be described in more detail by way of a manufacturing example and an experimental example.

### Manufacturing Example 1: Manufacture of Glass Articles

A plurality of glass substrates having various compositions according to Table 1 below were prepared and divided into SAMPLE #1, SAMPLE #2, and SAMPLE #3. Then, a glass article manufacturing process was performed on each sample according to the above-described method. Each sample was manufactured into a glass article with a thickness of 50 μm.

The composition of the glass article for each sample is shown in Table 1 below. In addition, the density, glass transition temperature, hardness, fracture toughness, brittleness, elastic modulus, thermal expansion coefficient, Poisson ratio, and crack initiation load of the glass article for each sample were measured and shown in Table 2 below.

Here, the glass transition temperature (Tg) was checked using differential thermal analysis (“DTA”) equipment by preparing 5 grams (g) of each composition and raising the temperature at a rate of 10 Kevin per minute (K/min) to the glass transition temperature range. The thermal expansion coefficient was checked using a thermo mechanical analyzer (“TMA”) by preparing a specimen with a size of 10×10×13 cubic millimeters (mm³) for each composition and raising the temperature at a rate of 10 K/min to the glass transition temperature range. Here, the glass transition temperature (Tg) means the temperature at which an amorphous polymer changes from a hard/glassy state to a soft/leathery state, or vice versa.

The elastic modulus and the Poisson ratio were checked using an elastic modulus tester by preparing a specimen with a size of 10×20×3 cubic meters (in³) for each composition and checking the stress and strain of the specimen.

The hardness and the fracture toughness were calculated using Equation 3 and Equation 4 below, respectively, by applying a load of 4.9 newtons (N) for 30 seconds with a Vickers hardness tester using a 19 μm size diamond tip.

$${H}_{V} = 1.854 \cdot \frac{F}{{a}^{2}} , \qquad ( 3 )$$

where Hv is Vickers hardness, F is a load, and α is an indentation length.

$$\frac{{K}_{lC} \cdot ϕ}{{H}_{V} \cdot {a}^{\frac{1}{2}}} = 0.15 \cdot K \cdot {( \frac{c}{a} )}^{- \frac{3}{2}} \qquad ( 4 )$$

where K_{IC} is fracture toughness, ϕ is a constraint index (ϕ≈3), Hv is Vickers hardness, K is a constant (=3.2), c is a crack length, and α is an indentation length.

The brittleness was calculated using Equation 5 below by applying a load of 4.9 N for 30 seconds using a Vickers hardness tester.

$$B = γ {P}^{- 1 / 4} \frac{{C}^{3 \text{/2}}}{a} \qquad ( 5 )$$

where B is brittleness, γ is a constant (2.39 Ni^{1/4}/μm/^{1/2}), P is an indentation load, α is an indentation length, and C is a crack length.

The crack initiation load was measured using a Vickers hardness tester equipment.

TABLE 1

| Sample group | | SAMPLE#1 | SAMPLE#2 | SAMPLE #3 |
|---|---|---|---|---|
| Composition | SiO₂ | 63.6 | 60.8 | 70.0 |
| | Al₂O₃ | 12.9 | 12.4 | 7.7 |
| | B₂O₃ | 4.7 | 4.6 | — |
| | MgO | — | 18.3 | 7.5 |
| | Na₂O | 2.7 | 2.4 | 12.7 |
| | ZnO | 1.6 | 1.5 | — |
| | CaO | 14.5 | — | — |
| | K₂O | — | — | 1.7 |

| | | | |
|---|---|---|---|
| Composition ratio (mol %) | 12.9:2.7 | 12.4:2.4 | 7.7:14.4 |
| Al₂O₃:R₂O | | | |
| Composition ratio (mol %) | 4.77 | 5.16 | 0.53 |
| Al₂O₃/R₂O | | | |

TABLE 2

Physical properties

| | | | |
|---|---|---|---|
| Density (g/cm³) | 2.560 | 2.512 | 2.460 |
| Glass transition temperature | 767 | 750 | 602 |
| Tg(° C.) | | | |
| Hardness (GPa) | 7.10 | 7.43 | 5.39 |
| Fracture toughness (MPa*m^{0.5}) | 0.919 | 1.067 | 0.87 |
| Brittleness (μm^{-0.5}) | 7.7 | 7.0 | 6.6 |
| Elastic modulus (GPa) | 85 | 92 | 72 |
| Thermal expansion coefficient | 35.2 | 30.4 | 89.0 |
| (10⁻⁷ K⁻¹) | | | |
| Poisson ratio | 0.243 | 0.254 | 0.220 |
| Crack initiation load (gf) | 200 | 500 | 500 |

Referring to Tables 1 and 2 above, SAMPLES #1 and #2 are glass articles made from glass compositions according to the present embodiment and SAMPLES #3 and #4 are glass articles which are comparative examples.

It can be seen that SAMPLE #1 and SAMPLE #2 have lower thermal expansion coefficients compared to than thermal expansion coefficients of SAMPLE #3. A low thermal expansion coefficient may mean that the glass has excellent impact resistance characteristics because the bonding strength of the components in the glass is high.

In addition, it can be seen that SAMPLE #1 and SAMPLE #2 have higher modulus of elasticity than the modulus of elasticity of SAMPLE #3. A high modulus of elasticity may mean that the bending characteristics of folding and unfolding are excellent.

Also, it can be seen that SAMPLE #1 and SAMPLE #2 have higher hardness than the hardness of SAMPLE #3. High hardness may mean excellent impact resistance characteristics.

Experimental Example 1: Impact resistance evaluation—pen drop evaluation (pen diameter 0.77π)

A pen drop test was conducted on SAMPLE #1 and SAMPLE #2 in Table 1 above. The pen drop test was conducted by dropping a pen with a diameter of 0.7π onto the surface of a fixed sample product to check a height at which the product surface is broken. The drop height of the pen was repeatedly changed by 0.1 centimeters (cm) within the range of 0.5 to 10 cm. When breakage finally occurred while the pen was repeatedly dropped, a height right before the breakage (that is, a maximum height at which the breakage did not occur) was determined as a limit drop height. The results are illustrated in Table 3. The pen drop test was conducted on each sample after a tempering operation was performed during the glass manufacturing process.

TABLE 3

| | Pen drop break height (cm) |
|---|---|
| SAMPLE #1 | 1.50 |
| SAMPLE#2 | 1.50 |

Referring to Table 3, SAMPLES #1 and #2 showed the same 1.50 cm and 1.50 cm, respectively.

Therefore, it can be seen that SAMPLE #1 and SAMPLE #2 show appropriate level of pen drop test results.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A glass article comprising, as a glass composition,
59 to 69 mole percents (mol %) of SiO₂,
8 to 18 mol % of Al₂O₃,
greater than 0 to 5 mol % of Na₂O,
greater than 0 to 5 mol % of ZnO, and
greater than 0 to 10 mol % of B₂O₃,
further comprising 10 to 20 mol % of CaO or 15 to 25 mol % of MgO, satisfying Relation 1 below, and having a thickness of 100 micrometers (μm) or less:
4.5≤Al₂O₃/Na₂O≤5.5 (Relation 1),
wherein, in Relation 1, Al₂O₃ and Na₂O represent contents (mol %) of corresponding components, respectively, in the glass composition.

2. The glass article of claim 1, wherein the thickness of the glass article is in a range of 20 to 100 μm.

3. The glass article of claim 1, wherein a thermal expansion coefficient of the glass article is in a range of 25*10⁻⁷ K⁻¹ to 40*10⁻⁷ K⁻¹.

4. The glass article of claim 1, wherein a glass transition temperature of the glass article is in a range of 700 to 800° C.

5. The glass article of claim 1, wherein a density of the glass article is in a range of 2.45 to 2.60 grams per cubic centimeters (g/cm³).

6. The glass article of claim 1, wherein an elastic modulus of the glass article is in a range of 80 to 95 gigapascals (GPa).

7. The glass article of claim 1, wherein a Poisson ratio of the glass article is in a range of 0.24 to 0.26.

8. The glass article of claim 1, wherein a hardness of the glass article is in a range of 7.0 to 7.5 GPa.

9. The glass article of claim 1, wherein a fracture toughness of the glass article is in a range of 0.95 to 1.10 MPa*m^{0.5}.

10. The glass article of claim 1, wherein a brittleness of the glass article is in a range of 6.5 to 8.0 μm^{-0.5}.

11. The glass article of claim 1, wherein a crack initiation load of the glass article is in a range of 150 to 550 gram-force (gf).

12. A glass composition comprising:
59 to 69 mol % of SiO₂,
8 to 18 mol % of Al₂O₃,
greater than 0 to 5 mol % of Na₂O,
greater than 0 to 5 mol % of ZnO, and
greater than 0 to 10 mol % of B₂O₃,
further comprising 10 to 20 mol % of CaO or 15 to 25 mol % of MgO, and satisfying Relation 1 below:
4.5≤Al₂O₃/Na₂O≤5.5 (Relation 1),
wherein, in Relation 1, Al₂O₃ and Na₂O represent contents (mol %) of corresponding components, respectively, in the glass composition.

13. A display device comprising:
a display panel comprising a plurality of pixels;
a cover window disposed on the display panel; and
an optically clear bonding layer disposed between the display panel and the cover window,
wherein the cover window comprises, as a glass composition, 59 to 69 mol % of SiO₂, 8 to 18 mol % of Al₂O₃, greater than 0 to 5 mol % of Na₂O, greater than 0 to 5 mol % of ZnO, and greater than 0 to 10 mol % of B₂O₃,
wherein the cover window further comprises 10 to 20 mol % of CaO or 15 to 25 mol % of MgO, satisfies Relation 1 below, and has a thickness of 100 μm or less:
4.5≤Al₂O₃/Na₂O≤5.5 (Relation 1),
wherein, in Relation 1, Al₂O₃ and Na₂O represent contents (mol %) of corresponding components, respectively, in the glass composition.

14. The display device of claim 13, wherein the cover window has the thickness of 20 to 100 μm.

15. The display device of claim 13, wherein the cover window has a thermal expansion coefficient of 25*10⁻⁷ K⁻¹ to 40*10⁻⁷ K⁻¹.

16. The display device of claim 13, wherein the cover window has a glass transition temperature of 700 to 800° C.

17. The display device of claim 13, wherein the cover window has a density of 2.45 to 2.60 g/cm³.

18. The display device of claim 13, wherein the cover window has an elastic modulus of 80 to 95 GPa.

19. The display device of claim 13, wherein the cover window has a Poisson ratio of 0.24 to 0.26.

20. The display device of claim 13, wherein the cover window has a hardness of 7.0 to 7.5 GPa.

21. The display device of claim 13, wherein the cover window has a fracture toughness of 0.95 to 1.10 MPa*m^{0.5}.

22. The display device of claim 13, wherein the cover window has a brittleness of 6.5 to 8.0 μm^{-0.5}.

23. The display device of claim 13, wherein the cover window has a crack initiation load of 150 to 550 gf.
